(19) United States
(12) Patent Application Publication
(10) Pub. No.: US 2019/0131163 A1
(43) Pub. Date: May 2, 2019

(54) WAFER SUSCEPTOR

(71) Applicant: NGK Insulators,LTD., Nagoya-City (JP)

(72) Inventors: Tatsuya KUNO, Nagoya -City (JP); Reo WATANABE, Handa-City (JP)

(73) Assignee: NGK Insulators,LTD., Nagoya-City (JP)

(21) Appl. No.: 16/231,662

(22) Filed: Dec. 24, 2018

Related U.S. Application Data
(63) Continuation of application No. PCT/JP2018/020125, filed on May 25, 2018.

(30) Foreign Application Priority Data
May 25, 2017 (JP) 2017-103767

(51) Int. Cl. H01L 21/687; H01L 21/683; H01L 21/302; H01L 21/67; H01J 37/32

(52) U.S. Cl. CPC H01L 21/68714; H01L 21/6833; H01J 37/32431; H01L 21/67103; H01L 21/302

(57) ABSTRACT

A wafer susceptor includes a conductive member attached to a surface of a plate, a through-hole penetrating through the plate and the conductive member, a screw hole formed in a conductive-member penetrating portion of the through-hole, a stopper surface formed in the conductive member, an insulation pipe screwed into the screw hole, and an insulating sealing member arranged between a plate-facing surface of the insulation pipe and the plate, wherein, with a contact surface of the insulation pipe coming into contact with the stopper surface of the conductive member, the insulation pipe is prevented from further advancing into the screw hole, a fore end surface of a sealing-member support portion of the insulation pipe is positioned at a predetermined position where the fore end surface does not contact the plate, and the sealing member is pressed between the plate-facing surface of the insulation pipe and the plate.

### BACKGROUND OF THE INVENTION

### 1. Field of the Invention

The present invention relates to a wafer susceptor for use in a semiconductor manufacturing apparatus.

### 2. Description of the Related Art

An electrostatic chuck, a vacuum chuck, etc. are known as wafer susceptors for use in semiconductor manufacturing apparatuses. An electrostatic chuck disclosed in Patent Literature (PTL) 1, for example, has a structure that a ceramic-made plate in which an electrode for generating electrostatic attraction force is embedded is bonded to a cooling board with a resin layer interposed therebetween, and that a through-hole penetrates through the plate and the cooling board. The through-hole is used to receive a lift pin for raising a wafer placed on the plate, and to supply gas to between a rear surface of the wafer and the plate. An insulation pipe is inserted into a portion (i.e., a cooling-board penetrating portion) of the through-hole, which penetrates through the cooling board. The insulation pipe is bonded to the cooling board with an adhesive interposed between an inner wall of the cooling-board penetrating portion and an outer peripheral surface of the insulation pipe.

### CITATION LIST

### Patent Literature

PTL 1: JP Utility Model 3154629

### SUMMARY OF THE INVENTION

However, when the insulation pipe and the cooling-board penetrating portion are bonded to each other using the adhesive, it is difficult to fill the adhesive without leaving vacancies. If the vacancies exist between the insulation pipe and the cooling-board penetrating portion, a problem arises in that the vacancies form conduction paths and insulation cannot be ensured. Furthermore, in the case in which there is a difference in air pressure between the inside and the outside of the insulation pipe, the adhesive may be peeled off due to the difference in air pressure. In addition, the insulation pipe and the cooling-board penetrating portion may be separated from each other due to repeated application of vibration and a moment of force during the use of the electrostatic chuck.

The present invention has been made with intent to solve the above-described problems, and a main object of the present invention is to ensure reliable isolation and electrical insulation between the inside and the outside of an insulation pipe.

The present invention provides a wafer susceptor including:

a plate made of ceramic and capable of attracting a wafer;

a conductive member attached to a surface of the plate on side opposite to a surface on which the wafer is to be placed;

a through-hole penetrating through the plate and the conductive member;

a screw hole formed in a conductive-member penetrating portion of the through-hole, the portion penetrating through the conductive member;

a stopper surface formed in the conductive member in intersecting relation to a central axis of the screw hole;

an insulation pipe having a contact surface that comes into contact with the stopper surface, the insulation pipe being screwed into the screw hole; and

an insulating sealing member fitted over a sealing-member support portion that is provided in projected form on a plate-facing surface of the insulation pipe, the insulating sealing member being arranged between the plate-facing surface of the insulation pipe and the plate,

wherein, with the contact surface of the insulation pipe coming into contact with the stopper surface of the conductive member, the insulation pipe is prevented from further advancing into the screw hole, a fore end surface of the sealing-member support portion of the insulation pipe is positioned at a predetermined position where the fore end surface does not contact the plate, and the sealing member is pressed between the plate-facing surface of the insulation pipe and the plate.

According to the wafer susceptor described above, with the contact surface of the insulation pipe coming into contact with the stopper surface of the conductive member, the insulation pipe is prevented from further advancing into the screw hole. Furthermore, the fore end surface of the sealing-member support portion of the insulation pipe is positioned at the predetermined position where the fore end surface does not contact the plate, and the sealing member is pressed between the plate-facing surface of the insulation pipe and the plate. Therefore, reliable isolation and electrical insulation between the inside and the outside of an insulation pipe can be ensured by the pressed sealing member. Moreover, since the fore end surface of the sealing-member support portion of the insulation pipe does not contact the plate, there is no risk that the plate may be damaged by the insulation pipe. In addition, since the insulation pipe can be repeatedly removed from the screw hole or screwed into the screw hole, the sealing member can be easily replaced.

In the wafer susceptor according to the present invention, the fore end surface of the sealing-member support portion of the insulation pipe may be positioned on side closer to the plate than a center of a cross-section of the pressed sealing member. With that feature, the pressed sealing member can be prevented from displacing beyond the fore end surface of the sealing-member support portion of the insulation pipe. In addition, the sealing member can be suppressed from being exposed to corrosive gas.

In the wafer susceptor according to the present invention, the insulation pipe may include an extended portion extending externally of the conductive member. When the insulation pipe has a large length, a comparatively great moment is applied between the insulation pipe and the conductive member. However, since the moment is received by both the contact surface of the insulation pipe and the stopper surface of the conductive member, the sealing performance is maintained.

In the wafer susceptor according to the present invention, a space allowing the pressed sealing member to be deformed may be provided at an open end of the screw hole on side closer to the plate. With that feature, the sealing member is not impeded by a cooling board from being pressed and deformed. In the above case, a width of the space may be greater than an inner diameter of the screw hole. With that feature, a wall of the cooling board made of metal, the wall defining the space, can be positioned sufficiently away from a conductive fluid within the insulation pipe.

In the wafer susceptor according to the present invention, the sealing-member support portion may be an annular projected portion provided in coaxial relation to the insulation pipe. With the provision of the annular projected portion, the present invention can be implemented with a comparatively simple structure.

In the wafer susceptor according to the present invention, a screw locking adhesive may be applied to the screw hole. With that feature, loosening of the insulation pipe from the screw hole can be prevented.

### BRIEF DESCRIPTION OF THE DRAWINGS

FIG. 1 is a perspective view of an electrostatic chuck 10.

FIG. 2 is a sectional view taken along A-A in FIG. 1.

FIG. 3 is an enlarged view of a region around an insulation pipe 30 in FIG. 2.

FIG. 4 is an enlarged perspective view of an annular projected portion 33.

FIG. 5 is a sectional view illustrating a procedure of attaching the insulation pipe 30 into a screw hole 26.

FIG. 6 is a sectional view illustrating the case in which a block member 50 is attached to a lower surface of a cooling board 20.

FIG. 7 is an enlarged sectional view illustrating the case in which a wall surrounding a space 28 is a tapered wall.

FIG. 8 is an enlarged view of a region around the insulation pipe 30 according to another embodiment.

FIG. 9 is an enlarged view of a region around the insulation pipe 30 according to still another embodiment.

FIG. 10 is an enlarged perspective view of a sealing-member support portion 133.

FIG. 11 is an enlarged perspective view of a sealing-member support portion 233.

### DETAILED DESCRIPTION OF THE INVENTION

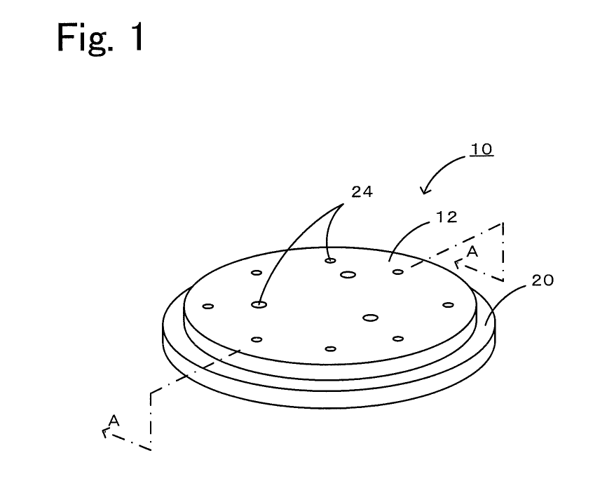

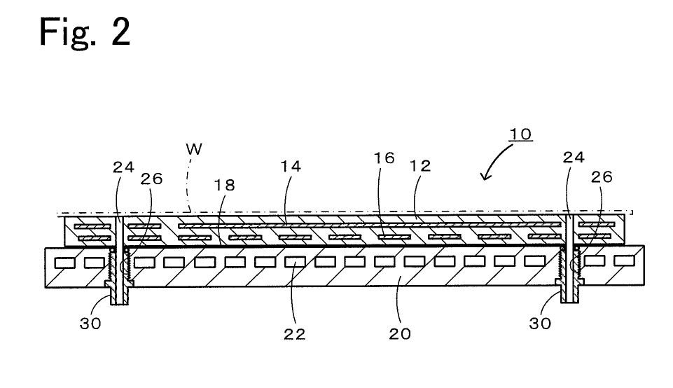

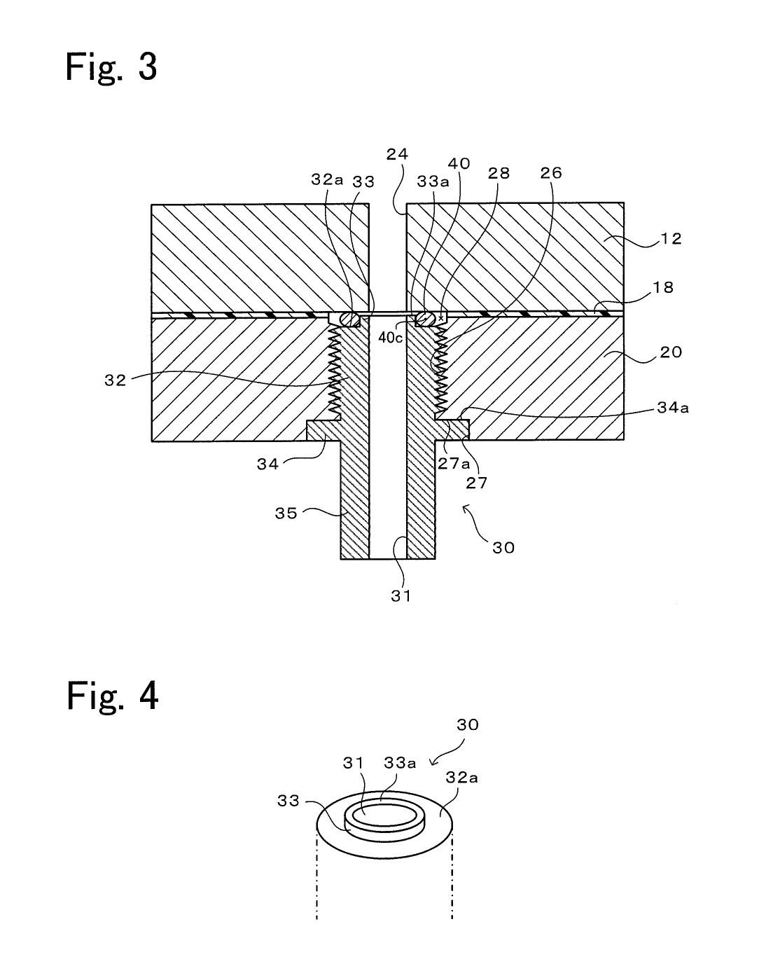

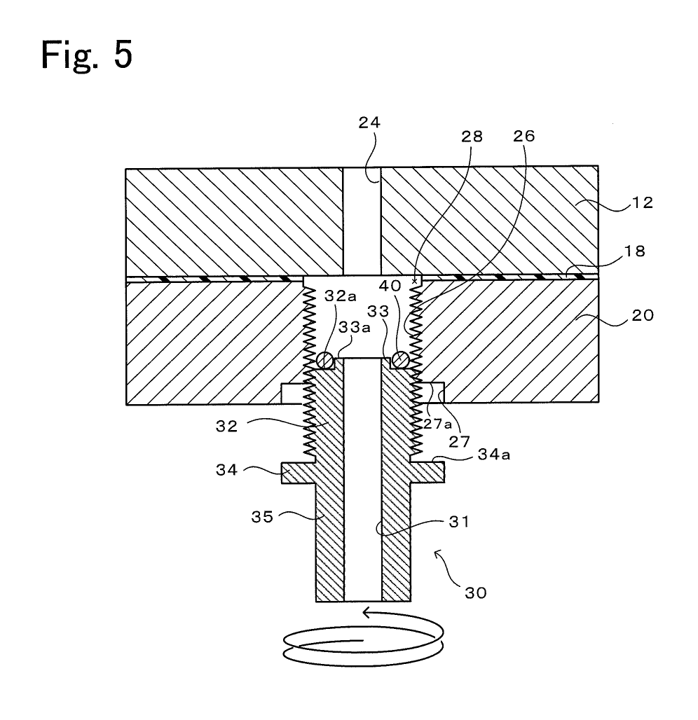

An embodiment of the present invention will be described below with reference to the drawings. FIG. 1 is a perspective view of an electrostatic chuck 10 that is one example of a wafer susceptor according to the present invention. FIG. 2 is a sectional view taken along A-A in FIG. 1, FIG. 3 is an enlarged view of a region around an insulation pipe 30 in FIG. 2, FIG. 4 is an enlarged perspective view of an annular projected portion 33, and FIG. 5 is a sectional view illustrating a procedure of attaching the insulation pipe 30 into a screw hole 26. It is to be noted that an electrostatic electrode 14, a resistance heating element 16, and a coolant path 22 are omitted in FIGS. 3 and 5.

The electrostatic chuck 10 includes a plate 12, a cooling board 20, a plurality of through-holes 24, and insulation pipes 30 (see FIGS. 2 and 3) that are inserted into the through-holes 24 and fixed there, respectively. An upper surface of the plate 12 serves as a surface on which a wafer W is to be placed.

As illustrated in FIG. 2, the plate 12 is made of ceramic (e.g., alumina or aluminum nitride), and it incorporates the electrostatic electrode 14 and the resistance heating element 16. The electrostatic electrode 14 is formed in the shape of a circular thin film. When a voltage is applied to the electrostatic electrode 14 via a power feed terminal (not illustrated) that is inserted from a lower surface of the electrostatic chuck 10, the wafer W is attracted to the plate 12 by electrostatic force generated between the surface of the plate 12 and the wafer W. The resistance heating element 16 is formed in a pattern that is drawn with a single stroke, for example, to be wired over an entire region of the plate 12. When the voltage is applied via a power feed terminal (not illustrated) that is inserted from the lower surface of the electrostatic chuck 10, the resistance heating element 16 generates heat, thus heating the wafer W.

The cooling board 20 is attached to a lower surface of the plate 12 with interposition of an adhesion layer 18 made of silicone resin therebetween. The adhesion layer 18 may be replaced with a bonding layer made of a brazing alloy. The cooling board 20 is a conductive member made of a conductive material (e.g., aluminum, an aluminum alloy, or a composite material of metal and ceramic), and it includes the coolant path 22 allowing passage of a coolant (e.g., water) therethrough. The coolant path 22 is formed such that the coolant passes over the entire region of the plate 12. The coolant path 22 has a supply port and a discharge port (both not illustrated) for the coolant.

The through-holes 24 penetrate through the plate 12, the adhesion layer 18, and the cooling board 20 in a thickness direction. The electrostatic electrode 14 and the resistance heating element 16 are designed to be not exposed to inner peripheral surfaces of the through-holes 24. A portion (i.e., a cooling-board penetrating portion) of each of the through-holes 24, which penetrates through the cooling board 20, is formed as a screw hole 26 having a greater diameter than another portion penetrating through the plate 12. A flange receiving portion 27 is provided, as illustrated in FIG. 3, at an open end of the screw hole 26 on the side opposite to the adhesion layer 18. The flange receiving portion 27 is a circular recess formed in the cooling board 20. An upper-side positioned bottom of the flange receiving portion 27 is used as a stopper surface 27a that is perpendicular to a central axis of the screw hole 26. A space 28 having a greater diameter than the screw hole 26 is provided at an open end of the screw hole 26 on the side closer to the adhesion layer 18.

The insulation pipe 30 is formed of an insulating material (e.g., alumina, mullite, PEEK, or PTFE). As illustrated in FIG. 3, the insulation pipe 30 has an axial hole 31 penetrating through the insulation pipe 30 along its central axis in an up-down direction. An inner diameter of the axial hole 31 is the same or substantially the same as that of a plate penetrating portion of the through-hole 24, which penetrates through the plate 12. The insulation pipe 30 includes a body portion 32, an annular projected portion 33, a flange portion 34, and an extended portion 35. The body portion 32 is in the form of a circular cylinder having a threaded outer peripheral surface. The threaded outer peripheral surface is meshed with the screw hole 26 of the cooling board 20. As illustrated in FIG. 4, the annular projected portion 33 is in the form of a circular cylinder and is projected from an upper surface of the body portion 32 (i.e., from a plate-facing surface positioned to face the plate 12) in coaxial relation to the body portion 32. A fore end surface 33a of the annular projected portion 33 defines a fore end surface of the insulation pipe 30, and an upper surface of the body portion 32 is formed as a stepped surface 32a. Preferably, a spacing between the fore end surface 33a of the annular projected portion 33 and the plate 12 is designed to be substantially zero (namely, when the tolerance is d (mm), for example, the spacing is d (mm)). An outer diameter of the annular projected portion 33 is smaller than that of the body portion 32. An O-ring 40 is fitted over the annular projected portion 33. The flange portion 34 is provided below the body portion 32. The flange portion 34 is fitted to the flange receiving portion 27 of the screw hole 26. A contact surface 34a defined by an upper surface of the flange portion 34 is held in contact with the stopper surface 27a. The extended portion 35 extends downward externally of the cooling board 20.

The O-ring 40 is an insulating sealing member and is disposed, as illustrated in FIG. 3, between the stepped surface 32a of the insulation pipe 30 and the lower surface of the plate 12. The O-ring 40 is formed of, for example, a fluorine-based resin (such as Teflon (registered trademark)). When attaching the insulation pipe 30, as illustrated in FIG. 5, the body portion 32 of the insulation pipe 30 is screwed into the screw hole 26 in a state in which the O-ring 40 is fitted over the annular projected portion 33 of the insulation pipe 30. Thereafter, when the flange portion 34 of the insulation pipe 30 is fitted to the flange receiving portion 27 and the contact surface 34a of the insulation pipe 30 is brought into contact with the stopper surface 27a of the flange receiving portion 27, the insulation pipe 30 is prevented from further advancing into the screw hole 26. In such a state, the fore end surface 33a of the annular projected portion 33 of the insulation pipe 30 is positioned at a predetermined position (i.e., a position illustrated in FIG. 3) where the fore end surface 33a does not contact the plate 12, and the O-ring 40 is pressed and deformed between the stepped surface 32a of the insulation pipe 30 and the lower surface of the plate 12. A degree of deformation of the O-ring 40 is determined depending on a distance between the stepped surface 32a of the insulation pipe 30 (i.e., a contact surface thereof with a lower surface of the O-ring) and the lower surface of the plate 12 (i.e., a contact surface thereof with an upper surface of the O-ring). The above distance is determined depending on positional relation among the stepped surface 32a of the insulation pipe 30, the contact surface 34a of the insulation pipe 30, and the stopper surface 27a of the cooling board 20. Thus, a rate of squeeze (amount of deformation) of the pressed and deformed O-ring 40 can be held constant. The fore end surface 33a of the annular projected portion 33 of the insulation pipe 30 is preferably positioned on the side closer to the plate 12 than a center 40c of a cross-section of the pressed and deformed O-ring 40.

A portion of the through-hole 24, which penetrates through the plate 12 and the adhesion layer 18, and the axial hole 31 of the insulation pipe 30 are communicated with each other in the up-down direction, thus forming a gas supply hole or a lift pin hole. The gas supply hole is a hole through which cooling gas (e.g., He gas) is supplied from below the cooling board 20. The cooling gas supplied to the gas supply hole is sprayed to a lower surface of the wafer W placed on the surface of the plate 12, thereby cooling the wafer W. The lift pin hole is a hole into which a lift pin (not illustrated) is inserted in a vertically movable manner. The wafer W placed on the surface of the plate 12 is raised by pushing up the lift pin.

A usage example of the electrostatic chuck 10 will be described below. The wafer W is placed on the surface of the plate 12 of the electrostatic chuck 10, and a voltage is applied to the electrostatic electrode 14, whereupon the wafer W is attracted to the plate 12 by electrostatic force. In that state, plasma CVD film formation or plasma etching is performed on the wafer W. In such a case, a temperature of the wafer W is controlled to be constant by applying a voltage to the resistance heating element 16 for heating the same, by circulating a coolant through the coolant path 22 in the cooling board 20, or by supplying the cooling gas to the gas supply hole. After the end of processing performed on the wafer W, the voltage applied to the electrostatic electrode 14 is reduced to zero to make the electrostatic force disappeared, and the lift pin (not illustrated) inserted into the lift pin hole is pushed up to raise the wafer W upward from the surface of the plate 12. The wafer W raised up by the lift pin is then carried to another place by a carrying apparatus (not illustrated). Thereafter, plasma cleaning is performed in a state in which the wafer W is not placed on the surface of the plate 12. At that time, the gas supply hole and the lift pin hole are filled with plasma.

According to the electrostatic chuck 10 of the embodiment described above in detail, with the contact surface 34a of the insulation pipe 30 coming into contact with the stopper surface 27a of the cooling board 20, the insulation pipe 30 is prevented from further advancing into the screw hole 26. In such a state, the fore end surface 33a of the annular projected portion 33 of the insulation pipe 30 is positioned at the predetermined position where the fore end surface 33a does not contact the plate 12, and the O-ring 40 is pressed and deformed between the stepped surface 32a of the insulation pipe 30 and the plate 12. Reliable isolation and electrical insulation between the inside and the outside of the insulation pipe 30 can be ensured by the O-ring 40 pressed and deformed as described above. In particular, insulation between a conductive fluid (e.g., plasma) within the insulation pipe 30 and the cooling board 20 made of metal can be ensured.

Furthermore, since the fore end surface 33a of the annular projected portion 33 of the insulation pipe 30 does not contact the plate 12, there is no risk that the plate 12 may be damaged by the insulation pipe 30. In particular, when the spacing between the fore end surface 33a of the annular projected portion 33 and the plate 12 is designed to be substantially zero, the O-ring 40 is protected by the annular projected portion 33 of the insulation pipe 30. Hence the lifetime of the O-ring 40 can be prolonged.

Moreover, since the insulation pipe 30 can be repeatedly removed from the screw hole 26 or screwed into the screw hole 26, the O-ring 40 can be easily replaced.

Still furthermore, the fore end surface 33a of the annular projected portion 33 of the insulation pipe 30 is positioned on the side closer to the plate 12 than the center 40c of the cross-section of the pressed and deformed O-ring 40. Therefore, the pressed and deformed O-ring 40 can be prevented from overriding the fore end surface 33a of the annular projected portion 33. In addition, the O-ring 40 can be suppressed from being exposed to corrosive gas.

Still furthermore, the insulation pipe 30 includes the extended portion 35 extending externally of the cooling board 20. When the insulation pipe 30 has a large length, a comparatively great moment is applied between the insulation pipe 30 and the cooling board 20. However, since the moment is received by both the contact surface 34a of the insulation pipe 30 and the stopper surface 27a of the cooling board 20, the sealing performance is maintained.

Since the space 28 allowing the O-ring 40 to be pressed and deformed is formed at the open end of the screw hole 26 on the side closer to the plate 12, the O-ring 40 is not impeded by the cooling board 20 from being pressed and deformed.

Since an inner diameter (width) of the space 28 is set to be greater than an inner diameter of the screw hole 26, a wall of the cooling board 20 made of a conductive material, the wall defining the space 28, can be positioned sufficiently away from the conductive fluid (e.g., plasma) within the insulation pipe 30, and the insulation properties can be further increased.

It is needless to say that the present invention is not limited to the above-described embodiment, and that the present invention can be implemented in various forms insofar as falling within the technical scope of the present invention.

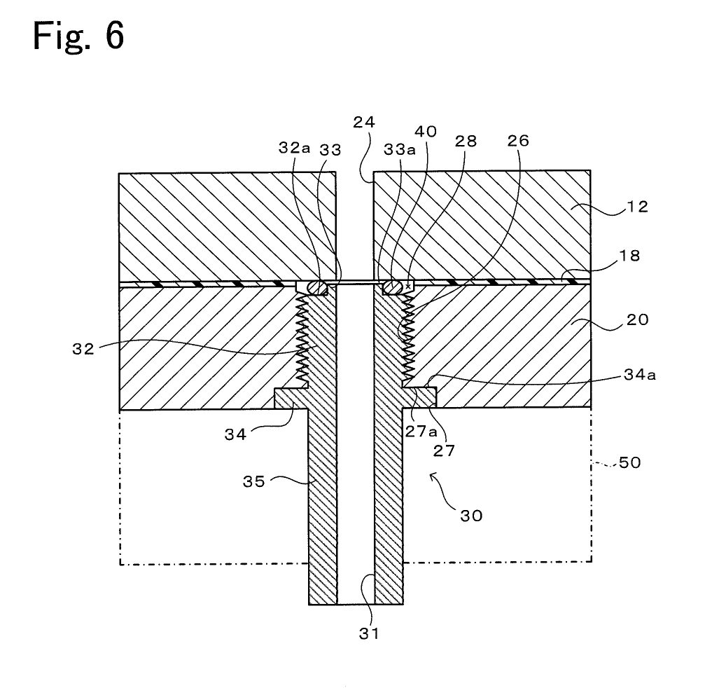

For instance, the above-described embodiment may be modified, as illustrated in FIG. 6, such that a block member 50 is joined to a lower surface of the cooling board 20, and that the extended portion 35 of the insulation pipe 30 is formed in a length enough to penetrate through the block member 50 in the up-and-down direction. In FIG. 6, the same components as those in the above-described embodiment are denoted by the same reference signs. When the extended portion 35 is long as in the above case, a greater moment is applied between the insulation pipe 30 and the cooling board 20. However, since the moment is received by both the contact surface 34a of the insulation pipe 30 and the stopper surface 27a of the cooling board 20, the sealing performance is maintained.

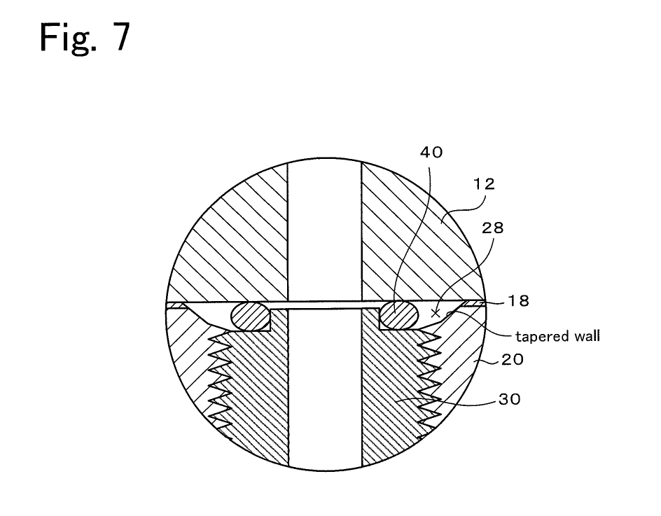

While, in the above-described embodiment, the wall surrounding the space 28 is formed as a vertical wall, the wall surrounding the space 28 may be formed as a tapered wall (i.e., a wall gradually spreading upward from below) as illustrated in FIG. 7. Reference signs in FIG. 7 denote the same components as those in the above-described embodiment. With such a modification, the wall of the cooling board 20 made of a conductive material, which defines the space 28, can be positioned further away from the conductive fluid (e.g., plasma) within the insulation pipe 30, and hence the insulation properties can be even further increased.

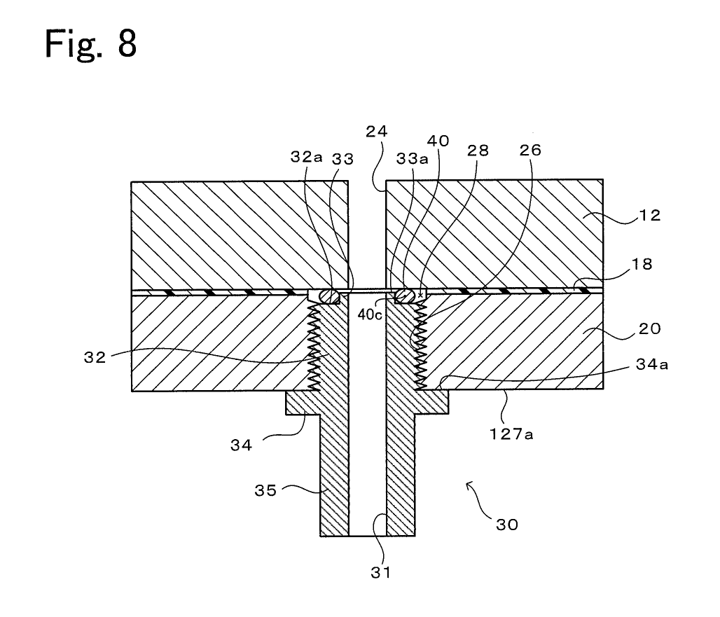

While, in the above-described embodiment, the upper-side positioned bottom of the flange receiving portion 27 is used as the stopper surface 27a, the flange receiving portion 27 may be omitted and a structure illustrated in FIG. 8 may be adopted. In FIG. 8, the same components as those in the above-described embodiment are denoted by the same reference signs. In the structure of FIG. 8, a portion of the lower surface (i.e., the surface on the side opposite to the plate 12) of the cooling board 20 around the open end of the screw hole 26 is used as a stopper surface 127a. With the contact surface 34a of the insulation pipe 30 coming into contact with the stopper surface 127a of the cooling board 20, the insulation pipe 30 is prevented from further advancing into the screw hole 26. In such a state, the fore end surface 33a of the annular projected portion 33 of the insulation pipe 30 is positioned at the predetermined position where the fore end surface 33a does not contact the plate 12, and the O-ring 40 is pressed and deformed between the insulation pipe 30 and the plate 12. Therefore, similar advantageous effects to those in the above-described embodiment are also obtained when the structure of FIG. 8 is adopted.

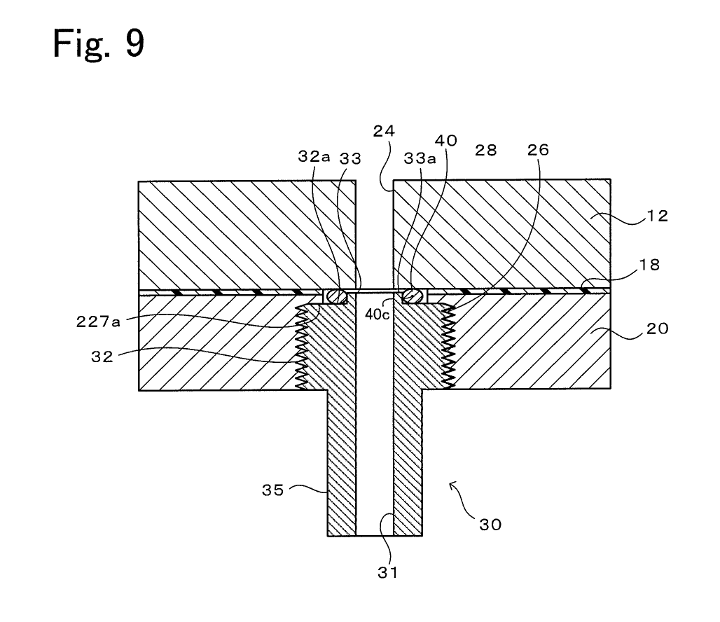

While, in the above-described embodiment, the upper-side positioned bottom of the flange receiving portion 27 is used as the stopper surface 27a, the flange receiving portion 27 and the flange portion 34 may be omitted and a structure illustrated in FIG. 9 may be adopted. In FIG. 9, the same components as those in the above-described embodiment are denoted by the same reference signs. In the structure of FIG. 9, the open end of the screw hole 26 on the side closer to the plate 12 is formed in a smaller diameter than the screw hole 26, and an upper-side positioned bottom of the screw hole 26 is used as a stopper surface 227a. Furthermore, the stepped surface 32a (functioning as a contact surface in the present invention) of the insulation pipe 30 comes into contact with the stopper surface 227a. With the stepped surface 32a of the insulation pipe 30 coming into contact with the stopper surface 227a of the cooling board 20, the insulation pipe 30 is prevented from further advancing into the screw hole 26. In such a state, the fore end surface 33a of the annular projected portion 33 of the insulation pipe 30 is positioned at the predetermined position where the fore end surface 33a does not contact the plate 12, and the O-ring 40 is pressed and deformed between the stepped surface 32a of the insulation pipe 30 and the plate 12. Therefore, similar advantageous effects to those in the above-described embodiment are also obtained when the structure of FIG. 9 is adopted.

While, in the above-described embodiment, the insulation pipe 30 includes the extended portion 35 extending downward from the flange portion 34, the extended portion 35 may be omitted. In such a case, a lower surface of the flange portion 34 may be positioned in flush with the lower surface of the cooling board 20.

In the above-described embodiment, a screw locking adhesive may be applied to the screw hole 26. The screw locking adhesive may be, for example, LOCKTITE (registered trademark). Loosening of the insulation pipe 30 from the screw hole 26 can be prevented by applying the screw locking adhesive. The strength of the screw locking adhesive is preferably set to such an extent that the insulation pipe 30 can be forcibly removed from the screw hole 26 by adding predetermined torque to the insulation pipe 30.

While, in the above-described embodiment, the diameter of the extended portion 35 of the insulation pipe 30 is set to be smaller than that of the flange portion 34, the diameter of the extended portion 35 may be equal to that of the flange portion 34. The above point is similarly applied to the extended portion 35 in FIG. 8. Moreover, the diameter of the extended portion 35 in FIG. 9 may be equal to that of the body portion 32.

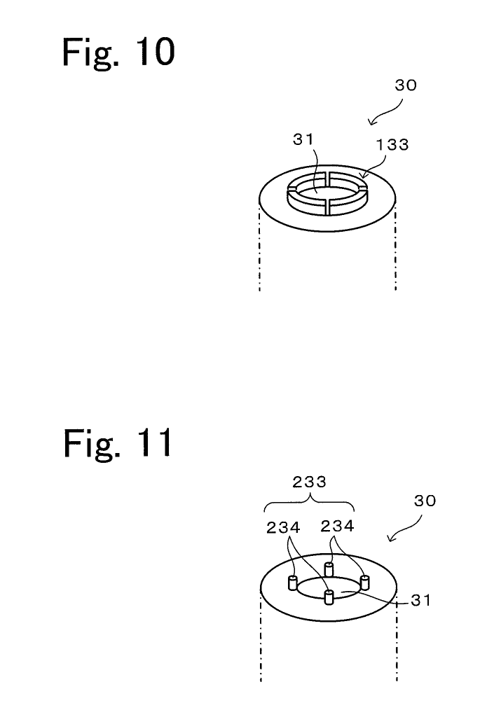

While, in the above-described embodiment, the insulation pipe 30 includes the annular projected portion 33 (see FIG. 4) that serves as the sealing-member support portion, the sealing-member support portion is not particularly limited to the annular projected portion 33. Sealing-member support portions 133 and 233 illustrated in FIGS. 10 and 11 may be adopted in other examples. In the sealing-member support portion 133 illustrated in FIG. 10, the annular projected portion 33 is divided into a plurality (four in the illustrated example) of pieces. In the sealing-member support portion 233 illustrated in FIG. 11, a plurality (four in the illustrated example) of circular columns 234 are arranged at equal intervals along a peripheral edge of an opening of the axial hole 31. The O-ring 40 (see FIGS. 3 and 5) is fitted over each of the sealing-member support portions 133 and 233. However, the annular projected portion 33 is more preferable than the sealing-member support portions 133 and 233 because the O-ring 40 can be more easily isolated from the corrosive gas.

While, in the above-described embodiment, the electrostatic chuck 10 includes the electrostatic electrode 14 and the resistance heating element 16 in the plate 12, the resistance heating element 16 may be omitted.

While, in the above-described embodiment, the electrostatic chuck 10 is disclosed as one example of the wafer susceptor, the present invention is not particularly limited to the electrostatic chuck, and the present invention may be applied to a vacuum check, etc.

This application claims the benefit of Japanese Patent Application No. 2017-103767 filed May 25, 2017, which is hereby incorporated by reference herein in its entirety.

What is claimed is:

1. A wafer susceptor comprising:
a plate made of ceramic and capable of attracting a wafer;
a conductive member attached to a surface of the plate on side opposite to a surface on which the wafer is to be placed;
a through-hole penetrating through the plate and the conductive member;
a screw hole formed in a conductive-member penetrating portion of the through-hole, the portion penetrating through the conductive member;
a stopper surface formed in the conductive member in intersecting relation to a central axis of the screw hole;
an insulation pipe having a contact surface that comes into contact with the stopper surface, the insulation pipe being screwed into the screw hole; and
an insulating sealing member fitted over a sealing-member support portion that is provided in projected form on a plate-facing surface of the insulation pipe, the insulating sealing member being arranged between the plate-facing surface of the insulation pipe and the plate,
wherein, with the contact surface of the insulation pipe coming into contact with the stopper surface of the conductive member, the insulation pipe is prevented from further advancing into the screw hole, a fore end surface of the sealing-member support portion of the insulation pipe is positioned at a predetermined position where the fore end surface does not contact the plate, and the sealing member is pressed between the plate-facing surface of the insulation pipe and the plate.

2. The wafer susceptor according to claim 1, wherein the fore end surface of the sealing-member support portion of the insulation pipe is positioned on side closer to the plate than a center of a cross-section of the pressed sealing member.

3. The wafer susceptor according to claim 1, wherein the insulation pipe includes an extended portion extending externally of the conductive member.

4. The wafer susceptor according to claim 1, wherein a space allowing the pressed sealing member to be deformed is provided at an open end of the screw hole on side closer to the plate.

5. The wafer susceptor according to claim 4, wherein a width of the space is greater than an inner diameter of the screw hole.

6. The wafer susceptor according to claim 1, wherein the sealing-member support portion is an annular projected portion provided in coaxial relation to the insulation pipe.

7. The wafer susceptor according to claim 1, wherein a screw locking adhesive is applied to the screw hole.
